(19) United States
(12) Patent Application Publication
(10) Pub. No.: US 2023/0318331 A1
(43) Pub. Date: Oct. 5, 2023

(54) ELECTRICAL VEHICLE CHARGING STATION AND MEDIA DISPLAY

(71) Applicant: LOOP, INC., El Segundo, CA (US)

(72) Inventor: Dustin Cavanaugh, El Segundo, CA (US)

(21) Appl. No.: 18/129,692

(22) Filed: Mar. 31, 2023

Related U.S. Application Data
(60) Provisional application No. 63/326,579, filed on Apr. 1, 2022.

(51) Int. Cl. H02J 7/00; H05K 5/02; H02G 11/00; B60L 53/30; B60L 53/18

(52) U.S. Cl. CPC H02J 7/0047; H05K 5/0247; H02G 11/00; B60L 53/30; B60L 53/18

(57) ABSTRACT

A media display and EV charging system including a display housing with a display screen mounted on at least one side the display housing and at least one EV charging unit mounted to sides of the display housing. The system includes a junction box disposed within the display housing, where the junction box being is in electrical communication with the display screen and the at least one EV charging unit, and wherein the junction box is configured to receive electrical power from a power source remote from the display housing.

### CROSS-REFERENCE TO RELATED APPLICATIONS

This application claims priority to U.S. Provisional Application No. 63/326,579, filed Apr. 1, 2022, the disclosure of which is incorporated by reference herein in its entirety.

### BACKGROUND

The background description provided herein is for the purpose of generally presenting the context of the disclosure. The work of the presently named inventors, to the extent it is described in this background section, as well as aspects of the description that may not otherwise qualify as prior art at the time of filing, are neither expressly nor impliedly admitted as prior art against the present disclosure.

The installation process for installing an outdoor digital media display for running on-premises or programmatic advertising and electric vehicle charging stations may both include the running of electrical conduit from a power source (e.g., electrical panel) of a property/building to the device in either above ground or below ground conduit raceways. Electrical wire may then run through that conduit, which is connected to the device to power and operate the device. Trenching, running conduit, and wiring electronic devices may be expensive, time consuming, or impractical in certain locations. Additionally, in some locations, space for installing electrical devices may not be abundant.

### SUMMARY

The following presents a simplified summary of the present disclosure in order to provide a basic understanding of some aspects of the disclosure. This summary is not an extensive overview of the disclosure. It is not intended to identify key or critical elements of the disclosure or to delineate the scope of the disclosure. The following summary merely presents some concepts of the disclosure in a simplified form as a prelude to the more detailed description provided below.

In an embodiment, the disclosure describes a media display and electric vehicle (EV) charging system. The system may include a display housing including one or more sides and forming a body cavity within the display housing, and a display screen mounted on at least one side of the one or more sides of the display housing. The system may include a display screen junction box disposed within the body cavity and electrically connected to the display screen, and a display screen wire running between the display screen junction box and a power source through a conduit. The system may include at least one EV charging unit mounted to one of the one or more sides of the display housing, and an EV charger junction box disposed within the body cavity and electrically connected to the EV charging unit. The EV charger junction box may be separate from the display screen junction box. The system may include an EV charger wire running between the EV charger junction box and the power source through the conduit.

In another embodiment, the disclosure describes a media display and electric vehicle (EV) charging system. The system may include a display housing including one or more sides, a display screen mounted on at least one side of the one or more sides of the display housing, and at least one EV charging unit mounted to one of the one or more sides of the display housing. The system may include a junction box disposed within the display housing. The junction box may be in electrical communication with the display screen and the at least one EV charging unit, and may receive electrical power from a power source remote from the display housing.

In another embodiment, the disclosure describes a method of installing an EV charging and media display system. The method may include providing a single raceway between an EV charger location and an electrical panel. The method may include installing electrical conduit within the single raceway, and pulling an electrical cable through the conduit such that the electrical cable spans the distance between the electrical panel and the EV charger location. The method may include pulling electrical cable into a junction box housed within a display housing. The method may include mounting one or more EV charging units on the display housing and mounting a display screen on the display housing. The method may include electrically connecting a charger power cable between the junction box and the one or more EV charging units, and electrically connecting a display power cable between the junction box and the display screen.

### BRIEF DESCRIPTION OF THE DRAWINGS

The invention may be better understood by references to the detailed description when considered in connection with the accompanying drawings. The components in the figures are not necessarily to scale, emphasis instead being placed upon illustrating the principles of the invention. In the figures, like reference numerals designate corresponding parts throughout the different views.

FIG. 1 is an embodiment of an EV charging and media display system in accordance with the disclosure;

FIG. 2 is a flow chart of an embodiment of installing the EV charging and media display system of FIG. 1;

FIG. 3 is a rear perspective view of another embodiment of an EV charging and media display system in accordance with the disclosure;

FIG. 4 is a front elevation view of the EV charging and media display system of FIG. 3;

FIG. 5 is a rear elevation view of the EV charging and media display system of FIG. 3;

FIG. 6 is a right side elevation view of the EV charging and media display system of FIG. 3;

FIG. 7 is a bottom view of the EV charging and media display system of FIG. 3;

FIG. 8 is a top view of the EV charging and media display system of FIG. 3;

FIG. 9 is a sectional view of a base of the EV charging and media display system of FIG. 3 as indicated in FIG. 4;

FIG. 10 is a partial exploded view of the EV charging and media display system of FIG. 3;

FIG. 11 is a close-up detail view of a portion of the EV charging and media display system of FIG. 3; and

FIG. 12 is a rear perspective view of the EV charging and media display system of FIG. 3 with upper and lower access panels removed.

### DETAILED DESCRIPTION

The present invention now will be described more fully hereinafter with reference to the accompanying drawings, which form a part hereof, and which show, by way of illustration, specific exemplary embodiments by which the invention may be practiced. These illustrations and exemplary embodiments are presented with the understanding that the present disclosure is an exemplification of the principles of one or more inventions and is not intended to limit any one of the inventions to the embodiments illustrated. The invention may be embodied in many different forms and should not be construed as limited to the embodiments set forth herein; rather, these embodiments are provided so that this disclosure will be thorough and complete, and will fully convey the scope of the invention to those skilled in the art. Among other things, the present invention may be embodied as methods or devices. Accordingly, the present invention may take the form of an entirely hardware embodiment, an entirely software embodiment or an embodiment combining software and hardware aspects. The following detailed description is, therefore, not to be taken in a limiting sense.

The figures depict preferred embodiments for purposes of illustration only. One skilled in the art will readily recognize from the following discussion that alternative embodiments of the structures and methods illustrated herein may be employed without departing from the principles described herein.

Installing outdoor digital media displays for running on-premises or programmatic advertising may include a similar process to that of installing electric vehicle charging stations. In both processes, electrical conduit may be run from a power source (e.g., electrical panel), such as in an electrical room of a property/building, to the device in either above ground or below ground conduit raceways. Electrical wiring running through that conduit may then be connected the electronic device to provide power. Traditionally, because electric vehicle charging stations may often require their own connection to electric wire to power the device, the charging station may be installed independently, next to, or near an outdoor digital media display that also may require its own independent wiring and conduit run in order receive power

In some embodiments, the disclosure describes an electrical vehicle charging station and media display system that, among other things, solves the problem of duplicative, expensive, inefficient, and time-consuming the efforts of site preparation, trenching, running conduit and independently wiring two separate electrical devices by instead providing and outdoor digital media display to which an electric vehicle (EV) charging station may be mounted. In some embodiments, the electrical wire/conduit that may be required to operate the EV charger may be fed through a junction box built into a body cavity of an outdoor digital media display such that both the outdoor digital media display and the EV charger may share the same conduit run and trenching from the original power source (e.g., electrical panel), which may significantly save installation costs, eliminate the visualization of exposed conduit/wire, and consolidate the operating footprint of these two separately powered devices into a single physical and/or electrical footprint.

In traditional systems that may include both an EV charger and a media display, the power and other electronic functionality may be integrated with one another such that if one of the two devices develops a problem or the functionality is somehow compromised, maintenance may require removal of both devices as one unit, resulting in suspended or ceased functionality of both the media display and the EV charger. In some embodiments of the disclosed systems, the digital media display and the EV charger may be modular, such that the two devices may be controlled, operate, and be powered independently. Accordingly, if power or other functional interruption to the media display causes it to go down or otherwise cease functioning, functioning of the EV charger may not be affected, and vice versa. Even so, the two devices may both share the same footprint and conduit raceways, saving cost, footprint space, and visual clutter to in the installed area. Moreover, in some embodiments, if one of the media display device or he EV charger may need to be upgraded, the upgrade to each individual device may be done modularly by only replacing one without interrupting the operation of the other. For example, if the media display device must be taken offline for repair or maintenance, the EV charger may still function due to the separate power and/or other electrical wiring.

Accordingly, the disclosed system may save significant time, expense, and materials during the installation of the media display and the EV charger as compared to traditional systems. Additionally, the system may visually consolidate the footprint of the devices into a single location so as to save functional walking space for passer-by tenants, employees, or customers. Moreover, if one of either the media display or the EV charger goes down, the operation of the other may be unaffected.

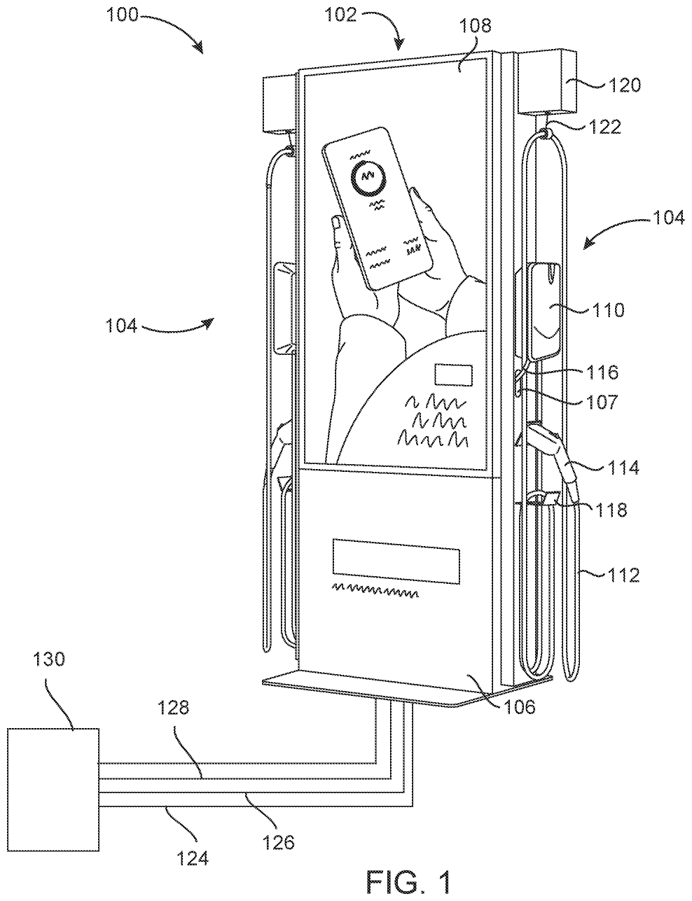

FIG. 1 shows an embodiment of an EV charging and media display system 100. The system 100 may include at least one media display unit 102 and at least one EV charging station 104. The media display unit 102 may include a display housing 106 and at least one display screen 108 disposed on one or more sides of the display housing. The display screen 106 may be configured to display electronic advertising or other media in the form of photographs, video, audio, interactive audio/visual programming or gaming, etc. In some embodiments, the display housing 106 may be generally rectangular in shape with four sides. The display housing 106 may be disposed and/or secured to the ground and may form a housing body cavity within the display housing. In some embodiments, the display housing 106 may include one or more power cable orifices 107 providing access into and/or out of the housing body cavity through the display housing wall.

In some embodiments, at least one EV charging station 104 may be mounted or otherwise secured to one side of the display housing 106. In some embodiments, each EV charging station 104 may include a charging unit 110, a charging cable 112, and a charging connector 114. In some embodiments, the charging unit 110 may be mounted or otherwise secured to the sides, front, and/or back of the display housing 106. In some embodiments, the charging unit 110 may be disposed within the display housing 106, such as mounted within the housing body cavity, for example, on one or more interior walls of the display housing 106. The charging cable 112 may connect the charging unit 110 to the charging connector 114, which may be configured to fit into an EV charging port to provide charging. In some embodiments, the EV charging station 104 may also include a cable bracket 118 and a cable retractor 120. The cable bracket 118 may hold the charging cable 112 and/or charging connector 114 in place, while the cable retractor 120 may have a retracting cable 122 that may connect to the charging cable 112. In some embodiments, the cable retractor 120 may include a winch or other tensioning mechanism that may retract the retracting cable 122 into the cable retractor so as to pull the charging cable 112 upwards. The cable retractor 120 may help to prevent or reduce the charging cable 112 from dragging on the ground. In some embodiments, the cable retractor 120 may be modular and/or removable so as to be usable separately from the charging unit 110, or so that the charging unit may be replaced or the cable retractor may be replaced without affecting or needing to replace the entire system.

In some embodiments, an EV charger power cable 116 may connect to the charging unit 110, run into the housing body cavity through the power cable orifice 107, and into an EV charger junction box disposed within the housing body cavity. In some embodiments, a media display power cable may connect the display screen 108 to a media display junction box that may also be disposed within the housing body cavity but may be separate from the EV charger junction box. An EV charger wire 126 may run through the bottom of the media display housing 106, through a conduit 124 that may be disposed within a raceway, and electrically connect to an electrical panel 130. In some embodiments, a media display wire 128 may also run through the bottom of the media display housing 106, through the conduit 124, and electrically connect to the electrical panel 130. In some embodiments, the media display wire may run through a different conduit in the same raceway as the conduit 124. In some embodiments, the separate EV charger junction box and media display junction box may provide for separate power sources for each device such that if one device may be damaged or needs to be taken offline for repair, etc., the other device may not be affected.

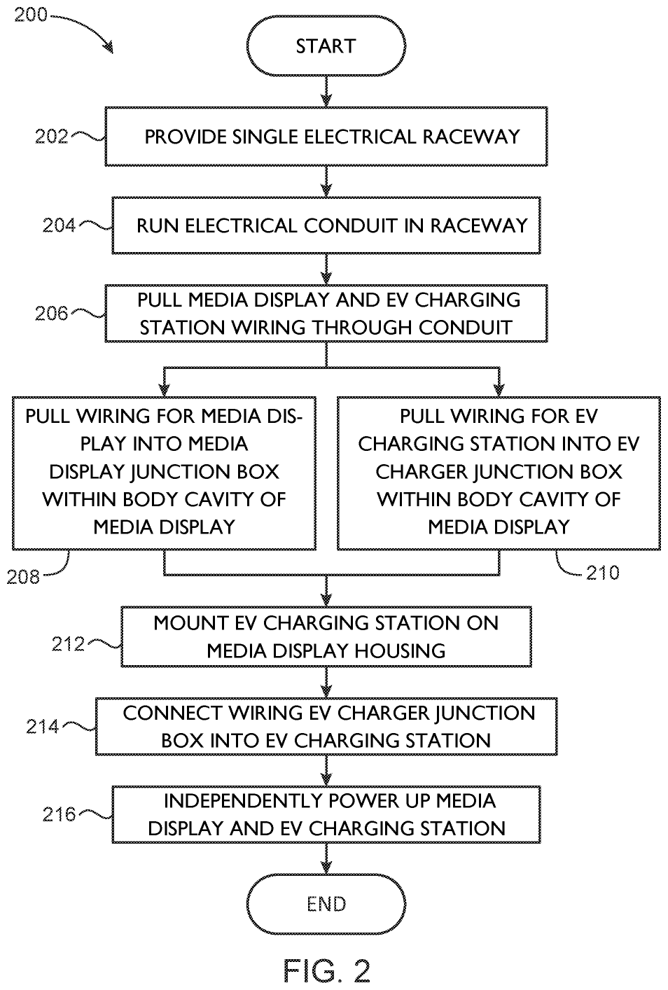

FIG. 2 is a flow chart of an embodiment of a method 200 of installing the EV charging and media display system described herein. At 202, the method may include providing a single electrical raceway running substantially between the EV charger location and an electrical panel, such as in or near a building. At 204, the method may include running electrical conduit from the electrical panel to the outdoor location where the media display and EV charging station are or will be located (e.g., a parking lot). At 206, the method may include pulling both the media display and charging station's electrical wire simultaneously through the raceway and/or conduit to an end point where the media display and EV charging station may be installed and powered up. At 208, the method may include pulling the electrical wire for the media display into a media display junction box that may be disposed in a body cavity of the media display and may power the media display through that junction box. At 210, the method may include, separately, pulling the electrical wiring for the EV charging station into a separate EV charger junction box that may be disposed in the body cavity of the media display and may power the charging station through that separate junction box.

At 212, the method may include mounting one or more EV charging stations on a side of the media display's housing closest to where the separate junction box for the EV charging station may be disposed. At 214, the method may include connecting the wiring from the EV charging station's separate junction box (from inside the media display's cavity) to the EV charging station such that the conduit/electrical wires may not be exposed except at a point of connection to the EV charging station itself. At 216, the method may include independently powering up both the outdoor media display and the EV charging station such that both devices operate separately but utilize the same physical footprint and body cavity for housing their respective junction boxes. In some embodiments, the method may include mounting additional electronic equipment that may also be powered through separate junction boxes disposed within the media display housing and share the raceway and/or conduit, such as security cameras, speakers, additional displays, payment terminals, etc.

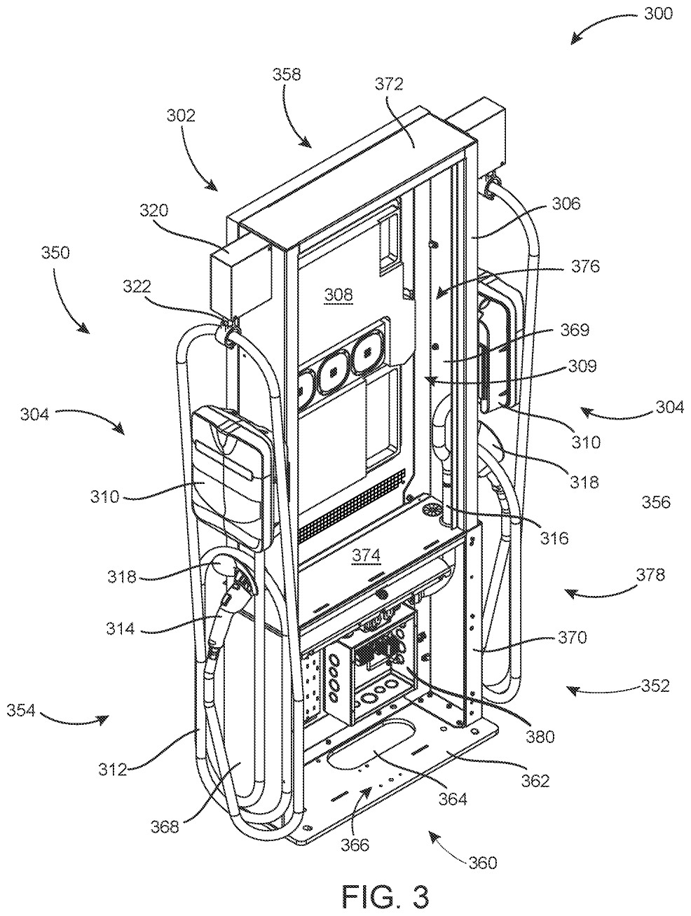

FIGS. 3-9 show another embodiment of a charging and media display system 300 showing a media display unit 302 with one or more EV charging stations 304. FIG. 3 shows a rear perspective view of the system 300 with the rear panel removed for purposes of illustration. The media display unit 302 may include a display housing 306 and at least one display screen 308 disposed on one or more sides of the display housing. The display screen 308 (shown from the rear in FIG. 3) may be configured to display electronic advertising or other media in the form of photographs, video, audio, interactive audio/visual programming or gaming, etc. In some embodiments, the display housing 306 may be generally rectangular in shape with four sides: a front portion 350, a rear portion 352, a first side portion 354, a second side portion 356, a top portion 358, and a bottom portion 360. The display housing 306 may form a housing body cavity 309 within the display housing, within which other components of the system 300 may be disposed. In some embodiments, the bottom portion 360 of the display housing 302 may include a base 362 that may 306 disposed and/or secured to the ground or other mounting surface. The base 362 may include at least one cable orifice 364 and one or more fastener orifices 366 formed therethrough. In some embodiments, the cable orifice 364 may include one orifice through which multiple cables may pass, or may be multiple orifices. In some embodiments, the cable orifice 364 and the fastener orifices 366 may be the same orifice.

In some embodiments, the first side portion 354 of the display housing 302 may include a first side wall 368 and the second side portion 356 of the display housing may include a second side wall 370. Each of the first and second side walls 368, 370 may be mounted to the base 362 and may be fastened in place using one or more suitable fasteners. The top portion 358 of the display housing 302 may include a housing top 372 such that the housing body cavity 309 may be defined within the housing top 372, the first and second side walls 368, 370, and the base 362. In some embodiments, a support beam 374 may be span substantially perpendicularly between the first and second side walls 368, 370, which may split the housing body cavity 309 into an upper cavity 376 and a lower cavity 378. In some embodiments, the upper cavity 376 may house components of the display screen 308 and the lower cavity 378 may house a junction box 380 and other components described in greater detail below.

In some embodiments, at least one EV charging station 304 may be mounted or otherwise secured to the first side wall 368 and/or the second side wall 370 of the display housing 306. In some embodiments, each EV charging station 304 may include a charging unit 310, a charging cable 312, and a charging connector 314. In some embodiments, the charging unit 310 may be mounted or otherwise secured to the side portions 354, 356, the front portion 350, and/or the back portion 352 of the display housing 306. In some embodiments, the charging unit 310 may be disposed within the display housing 306, such as mounted within the housing body cavity 309, for example, on an interior wall 369 of the display housing 306. The charging cable 312 may connect the charging unit 310 to the charging connector 314, which may be configured to fit into an EV charging port to provide charging. In some embodiments, the EV charging station 304 may also include a cable bracket 318 and a cable retractor 320. The cable bracket 318 may hold the charging cable 312 and/or charging connector 314 in place, while the cable retractor 320 may have a retracting cable 322 that may connect to the charging cable 112. In some embodiments, the cable retractor 320 may include a winch or other tensioning mechanism that may retract the retracting cable 322 into the cable retractor so as to pull the charging cable 312 upwards into a stowed position. In some embodiments, the cable retractor 320 may help to prevent or reduce the charging cable 312 from dragging on the ground or from otherwise being damaged. In some embodiments, the cable retractor 320 may be modular and/or removable so as to be usable separately from the charging unit 310, or so that the charging unit may be replaced or the cable retractor may be replaced without affecting or needing to replace the entire system 304. In some embodiments, the display housing 306 may include one or more power cable orifices 307 providing access into and/or out of the housing body cavity 309 through the first and/or second side wall 368, 370.

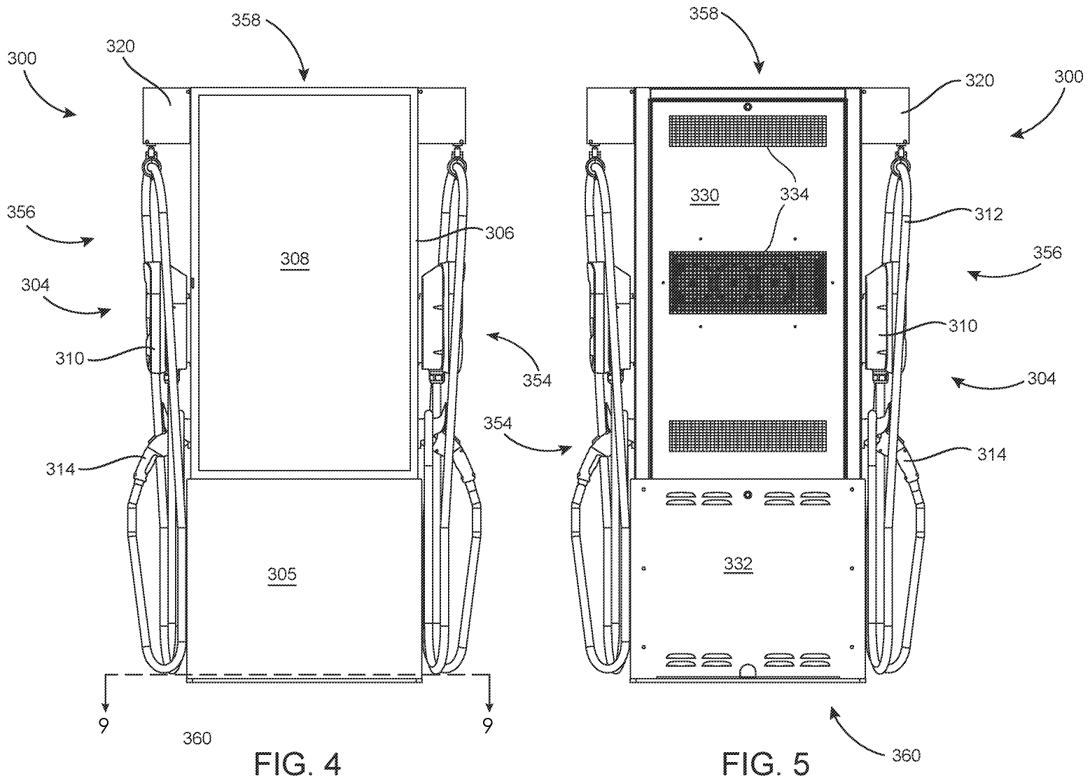

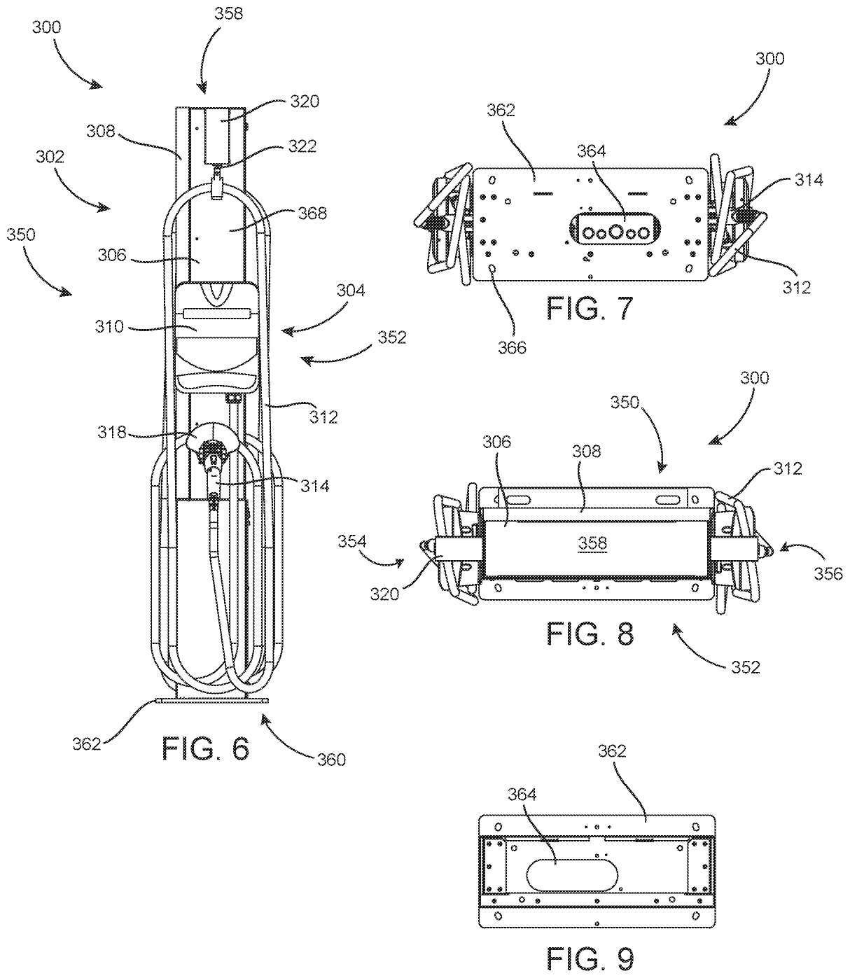

FIG. 4 shows a front view of the charging and media display system 300. In some embodiments, the display screen 308 may be a liquid crystal display (LCD) screen, light emitting diode (LED) screen, or other suitable display technology for displaying media such as images, videos, graphics, etc. In some embodiments, a lower portion of the front portion 350 of the display housing 306 may include a front panel 305 that may include graphics, advertisements, text, or another media display. FIG. 5 shows a rear view of the charging and media display system 300 with a upper access panel 330 and a lower access panel 332 fastened in place to enclose the display housing cavity 309 within. In some embodiments, the upper access panel 330 and/or the lower access panel 332 may include one or more vents 334 or other ventilation features to allow air to circulate in and out of the cavity 309 of the housing 306. The upper and lower access panels 330, 332 may be removable to perform maintenance on the components within. FIGS. 6, 7, and 8 show right side, bottom, and top views, respectively of the display housing 306. FIG. 9 shows a sectional view of the display housing 306 as indicated in FIG. 4, looking down upon the base 362. In some embodiments, the at least one cable orifice 364 may include multiple orifices in the base 362.

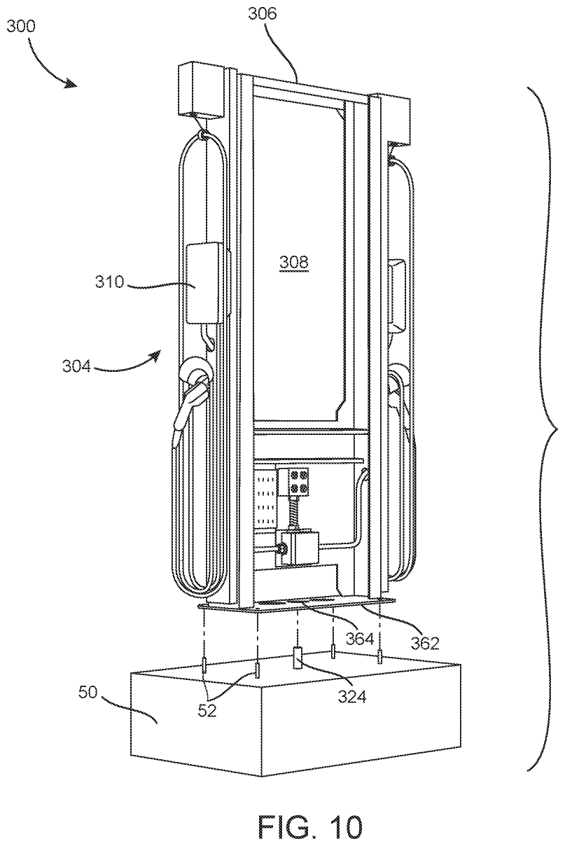

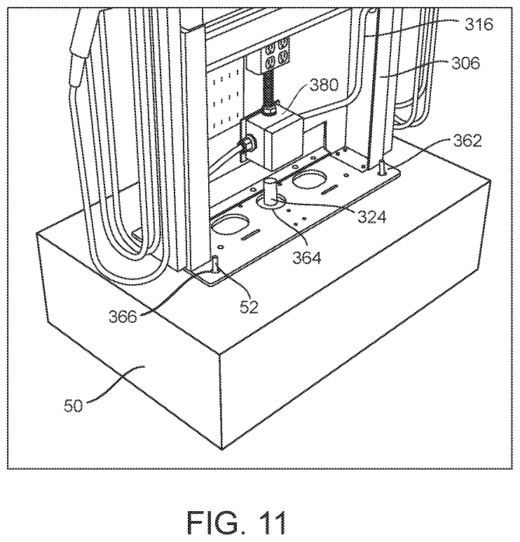

FIG. 10 shows a partially exploded view of the display housing 306 positioned over a mounting platform 50, such as cement pad, asphalt parking area, or etc. In some embodiments, the mounting platform 50 may include one or more fasteners 52, such as bolts, that may fit through the one or more fastener orifices 366 formed into the base 362. In some embodiments, nuts or other fastening mechanisms may secure the base against the mounting platform 50 using the one or more fasteners 52. In some embodiments, a hollow conduit 324 may also extend from the mounting platform 50. As described in more detail below, the conduit 324 may provide a pathway for power or other cabling to reach the display housing 306 from a remote location, such as an electrical panel or other power source, via a raceway as described with respect to FIG. 1. FIG. 11 shows the display housing 306 and base 362 mounted onto the mounting platform 50 with the fasteners 52 through the fastener orifices 366 and the conduit 324 passing through the cable orifice 364.

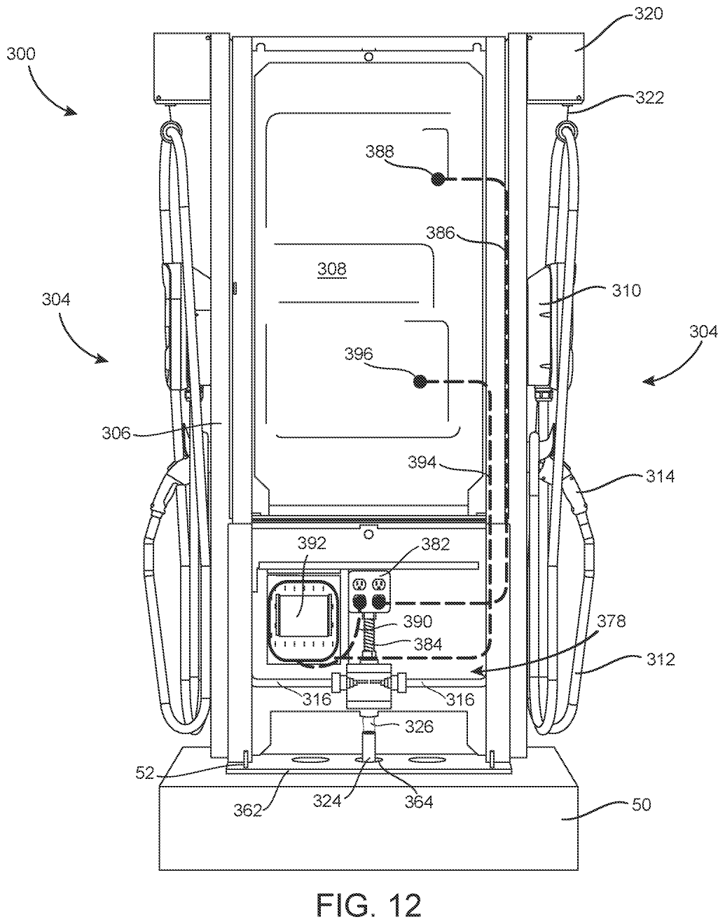

Referring to FIG. 12, in some embodiments, a power cable 326, which may be sheathed within the conduit 324, may run through the cable orifice 364 in the base 362 of the display housing 306 and electrically connect to a junction box 380 house within the lower cavity 378. The power cable 326 and the conduit 324 may be buried in the ground, disposed within a raceway, or otherwise configured so as to provide power from a power source such the electrical panel 130 shown in FIG. 1. In some embodiments, the an EV charger power cable d may connect to each charging unit 310, run into the housing body cavity 309 through the one or more power cable orifices 307, and into the junction box 380. Each EV charger power cable 316 may accordingly provide an electrical connection between the junction box 380 and each EV charging station mounted to the display housing 306. In some embodiments, the junction box 380 may also provide an electrical connection to one or more power outlets 382 disposed within the lower cavity 378 through a media power cable 384.

In some embodiments, a display power cable 386 may provide an electrical connection between a power port 388 of the display screen 308 and the power outlet 382. In some embodiments, a router power cable 390 may provide an electrical connection between the power outlet 382 and a communications module 392 (e.g., cellular router, Wifi router, Bluetooth antenna, near field communication (NFC) antenna, etc.) configured to access one or more networks either wirelessly or via wired, such as a cellular network or the internet, or have wired or wireless communications directly with a computing device. In some embodiments, a media data cable 394 may provide an electronic communication between a data port 396 of the display screen 308 and the communications module 392 so as to transfer data between the display screen and the communications module. In some embodiments, the communications module 392 may provide a one- or two-way wireless network connection that may provide for media content to be transmitted to the display screen 308 for display.

In some embodiments, when repairs, maintenance, upgrades, etc., may be performed on the system 300, the modular nature of the components may allow for portions of the system to be taken offline without affecting the performance and/or usability of other components. For example, in some embodiments, each of the EV charging units 310 may be individual disconnected from the junction box 380 without affecting power availability to either the other of the EV charging units or the power outlet 382. Accordingly, a single EV charging unit 310 may be taken offline without interrupting power to the display screen 308, the communications module 392, or the other EV charging unit(s). Similarly, if the display screen 308 or the communications module 392 may be repaired or replaced, they may each be taken offline by unplugging their respective power cables (i.e., the display power cable 386 or the router power cable 390) without interrupting power flowing to the EV charging unit(s) 310 or other components. In some embodiments, one or both of the display power cable 386 and/or the router power cable 390 may connect directly into the junction box 380 and bypass the power outlet 382, or some embodiments may not have a power outlet at all.

In some embodiments, the modular attachment of the charging units 310 to the exterior of the display housing 306 (e.g., on the first and second side walls 368, 370) may also reduce heat build-up within housing body cavity 309. For example, many electrical components, such as display screens, charging units, etc., may give off heat as a byproduct and often cooling measures (e.g., fans, heat exchangers, air conditioning, etc.) may be implemented to mitigate heat build-up. In embodiments of the system 300 in which the EV charging units 310 may be disposed outside the housing body cavity 309, fewer cooling measures may be needed to maintain an operationally acceptable temperature for the components within the display housing 306. Additionally, the modular nature of the system's components may provide for various design features for each individual component without significantly impacting the design of the other components.

Upon reading this disclosure, those of skill in the art will appreciate still additional alternative structural and functional designs for the systems and methods described herein through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the systems and methods disclosed herein without departing from the spirit and scope defined in any appended claims.

1. A media display and electric vehicle (EV) charging system comprising:
a display housing including one or more sides and forming a body cavity within the display housing;
a display screen mounted on at least one side of the one or more sides of the display housing;
a display screen junction box disposed within the body cavity and electrically connected to the display screen;
a display screen wire running between the display screen junction box and a power source through a conduit;
at least one EV charging unit mounted to one of the one or more sides of the display housing;
an EV charger junction box disposed within the body cavity and electrically connected to the EV charging unit, the EV charger junction box being separate from the display screen junction box; and
an EV charger wire running between the EV charger junction box and the power source through the conduit.

2. The system of claim 1 further comprising a cable retractor disposed on the display housing, the cable retractor configured to provide tension on a charging cable connected to the EV charging unit.

3. The system of claim 1, wherein the EV charger wire is configured to be disconnected from the EV charging unit without interrupting electrical communication between the display screen junction box and the display screen.

4. The system of claim 1, wherein display screen wire is configured to be disconnected from the display screen junction box without interrupting electrical communication between the EV charging unit and the EV charger junction box.

5. The system of claim 1, wherein the conduit is disposed in a raceway buried beneath a mounting surface.

6. A media display and electric vehicle (EV) charging system comprising:
a display housing including one or more sides;
a display screen mounted on at least one side of the one or more sides of the display housing;
at least one EV charging unit mounted to one of the one or more sides of the display housing; and
a junction box disposed within the display housing, the junction box being in electrical communication with the display screen and the at least one EV charging unit, and wherein the junction box is configured to receive electrical power from a power source remote from the display housing.

7. The system of claim 6 further comprising a power outlet in electrical communication with the junction box.

8. The system of claim 6, wherein the display screen is in electrical communication with the junction box via the power outlet.

9. The system of claim 6 further comprising a communications module in electrical communication with the junction box, the communications module being configured to access one or more communication networks.

10. The system of claim 9, wherein the communications module is in electronic communication with the display screen so as to transfer electronic data to the display screen.

11. The system of claim 6, wherein the electrical communication between the display screen and the junction box is configured so as to be interrupted without affecting the electrical communication between the junction box and the at least one EV charging unit.

12. The system of claim 6, wherein the at least one EV charging unit is mounted on an exterior surface of the one or more sides of the display housing.

13. The system of claim 12, wherein an EV charging cable provides the electrical communication between the EV charging unit and the junction box by passing through one of the one or more sides of the display housing.

14. The system of claim 6 further comprising a cable retractor disposed on the display housing, the cable retractor configured to provide tension on a charging cable connected to the at least one EV charging unit.

15. The system of claim 6 further comprising:
a power outlet in electrical communication with the junction box;
a communications module in electrical communication with the power outlet, the communications module being configured to access one or more communication networks;
a display power cable providing electrical communication between a power port of the display screen and the power outlet; and
a media data cable providing electronic communication between a data port of the display screen and the communications module.

16. A method of installing an EV charging and media display system, the method comprising:
providing a single raceway between an EV charger location and an electrical panel;
installing electrical conduit within the single raceway;
pulling an electrical cable through the conduit such that the electrical cable spans the distance between the electrical panel and the EV charger location;
pulling electrical cable into a junction box housed within a display housing;
mounting one or more EV charging units on the display housing;
mounting a display screen on the display housing;
electrically connecting a charger power cable between the junction box and the one or more EV charging units; and
electrically connecting a display power cable between the junction box and the display screen.

17. The method of claim 16 further comprising installing a power outlet in electrical communication with the junction box.

18. The method of claim 17 wherein the display screen is in electrical communication with the junction box via the power outlet.

19. The method of claim 6 further comprising installing a communications module within the display housing, the communications module being in electrical communication with the junction box and configured to access one or more communication networks.

20. The system of claim 19, wherein the communications module is in electronic communication with the display screen so as to transfer electronic data to the display screen.
